(19) United States
(12) Patent Application Publication
(10) Pub. No.: US 2016/0224413 A1
(43) Pub. Date: Aug. 4, 2016

(54) SEMICONDUCTOR MEMORY DEVICE AND METHOD OF CHECKING OPERATION STATE THEREOF

(71) Applicant: SK hynix Inc., Icheon-si Gyeonggi-do (KR)

(72) Inventors: Yong Hyun KWON, Icheon-si Gyeonggi-do (KR); Won Sun PARK, Seoul (KR)

(21) Appl. No.: 14/792,261

(22) Filed: Jul. 6, 2015

(30) Foreign Application Priority Data
Feb. 3, 2015 (KR) 10-2015-0016749

(51) Int. Cl. G06F 11/10; G11C 29/52; G11C 29/08; G06F 11/263

(52) U.S. Cl. CPC G06F 11/1012; G06F 11/2635; G06F 11/1072; G11C 29/52; G11C 29/08

(57) ABSTRACT

Disclosed are a semiconductor memory device and a method of checking an operation state thereof. The semiconductor memory device includes: a micro configured to output a data generating code according to a state checking operation command; and a step code generating unit configured to generate a step code for an operation currently performed by a storage device according to the data generating code, and output ROM data including the step code, in which the micro generates a state code for the operation currently performed by the storage device and an operation code for a segmentalized step of the operation according to the ROM data.

### CROSS-REFERENCE TO RELATED APPLICATION

The present application claims priority to Korean patent application number 10-2015-0016749, filed on Feb. 3, 2015, the entire disclosure of which is herein incorporated by in its entirety.

### BACKGROUND

1. Field

The invention relates to a semiconductor memory device and a method of checking an operation state thereof, and more particularly, to a semiconductor memory device for checking an operation state thereof in real time, and a method of checking an operation state thereof.

2. Discussion of Related Art

A semiconductor memory device is generally divided into a volatile semiconductor memory device and a non-volatile memory device. The volatile semiconductor memory device has a high read and write rate, but has a disadvantage in that stored contents disappear when power supply is interrupted. By contrast, the non-volatile semiconductor memory device maintains stored contents even though power supply is interrupted. Accordingly, the non-volatile semiconductor memory device is used for storing data which needs to be preserved regardless of the supply of power.

A flash memory among the non-volatile semiconductor memory devices is widely used as voice and image data storage media of user devices, such as a computer, a mobile phone, a Personal Digital Assistant (PDA), a digital camera, a camcorder, a voice recorder, an MP3 player, a handheld PC, a game play device, a facsimile, a scanner, and a printer. Further, the flash memory may be configured in a detachable card type, such as a Multimedia Card (MMC), a Secure Digital Card (SD card, a smartmedia card, or a compact flash card, and may be used as a main storage device in a large capacity storage device, such as a Universal Serial Bus (USB) memory and a Solid State Drive (SSD).

In the meantime, the semiconductor device provides information about an operation state according to a demand of a user, and when the semiconductor device is being operated, it is difficult to provide the user with detailed information about a currently performed operation.

### SUMMARY

An embodiment of the invention provides a semiconductor memory device, including a micro configured to output a data generating code according to a state checking operation command. The semiconductor memory device may also include a step code generating unit configured to generate a step code for an operation currently performed by a storage device according to the data generating code, and output ROM data including the step code. Further, the micro generates a state code for the operation currently performed by the storage device and an operation code for a segmentalized step of the operation according to the ROM data.

An embodiment of the invention provides a method of checking an operation state of a semiconductor memory device, including setting a step code for each operation performed by a storage device. The method also includes generating the step code for one operation currently performed by the storage device according to a state checking command. The method also includes generating a state code for the one operation currently performed by the storage device and an operation code for a segmentalized step of the one operation according to the step code. The method also includes outputting data including the operation code according to a state checking enable signal.

In an embodiment, a semiconductor memory device may include a micro configured to receive a state checking operation command and output a data generating code and generate a state code and an operation code according to ROM data and output micro data that includes the state code and the operation code. The semiconductor memory device may also include a step code generating unit configured to generate a step code according to the data generating code and output the ROM data that includes the step code.

### BRIEF DESCRIPTION OF THE DRAWINGS

FIG. 1 is a block diagram for describing a semiconductor system according to an embodiment of the invention;

FIG. 2 is a block diagram for describing a memory chip according to an embodiment of the invention;

FIG. 3 is a block diagram for describing a control logic and a storage device controller in detail;

FIG. 4 is a diagram for describing a step code and an operation code in detail; and

FIG. 5 is a diagram for describing a method of loading operation code data to a common bus in detail.

### DETAILED DESCRIPTION

Hereinafter, an embodiment of the invention will be described in detail with reference to the accompanying figures. However, the invention is not limited to embodiments to be disclosed below, but various forms different from each other may be implemented. However, the embodiments are provided to be completely known to those skilled in the art. The invention has been made in an effort to provide a semiconductor memory device capable of checking an operation state thereof in real time, and a method of checking an operation state thereof. According to the embodiments of the invention, it is possible to check an operation state even when a semiconductor memory device is being operated, check even a detail step of a currently performed operation, and provide a user with more detailed information, thereby improving reliability of the semiconductor memory device.

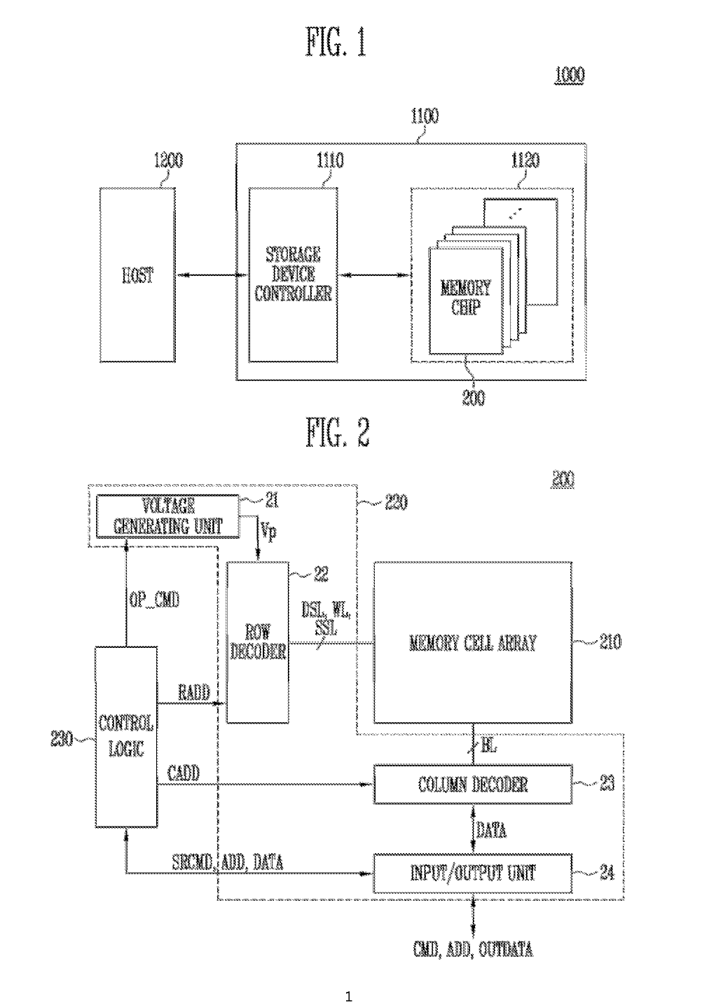

Referring to FIG. 1, a block diagram for describing a semiconductor system according to an embodiment of the invention is described.

In FIG. 1, a semiconductor system 1000 includes a semiconductor memory device 1100 in which data is stored, and a host 1200 which is a user device electrically coupled to the semiconductor memory device 1100.

The semiconductor memory device 1100 may be configured by a solid state disk, a Solid State Drive (SSD), a PC card (Personal Computer Memory Card International Association (PCMCIA), a Compact Flash Card (CFC), a Smart Media Card (SMC), a memory stick, a Multi Media Card (MMC) (Reduced Size (RS)-MMC, MMC-micro), a Secure Digital (SD) card, (a miniSD card, a microSD card, and a Secure Digital High Capacity (SDHC) card) or a Universal Flash Storage (UFS) device.

The host 1200 may be configured by a device, such as a personal or portable computer, a PDA, a Portable Media Player (PMP), and an MP3 player. The host 1200 and the semiconductor memory device 1100 may be electrically coupled with each other by a standardized interface, such as a USB, a Small Computer System Interface (SCSI), an Enhanced Small Device Interface (ESDI), Serial Advanced Technology Attachment (SATA), Serial Attached SCSI (SAS), Peripheral Component Interconnect (PCI)-express, or an Integrated Drive Electronics (IDE) interface.

The aforementioned semiconductor memory device 1100 basically includes a storage device controller 1110 and a storage device 1120. The storage device controller 1100 outputs various commands and data to the storage device 1120 so that the storage device 1120 may perform various operations according to the command received from the host 1200. The storage device 1120 includes a plurality of memory chips 200 configured so as to perform various operations, such as an erase operation, a program operation, and a read operation according to various commands and data output from the storage device controller 1110. The memory chips 200, which are devices for storing data, may be implemented by a Dynamic Random Access Memory (DRAM), a Static Random Access Memory (SRAM), a Magnetic Random Access Memory (MRAM), or a flash memory device.

When a state checking command is received from the host 1200, the semiconductor memory device 1100 outputs information about a current state of the selected memory chip 200. To this end, the storage device controller 1110 of the semiconductor memory device 1100 generates an operation code for a current performed operation among various operations performed by the memory chip 200. Further, the memory chip 200 outputs final data including the operation code generated by the storage device controller 1110 to the outside.

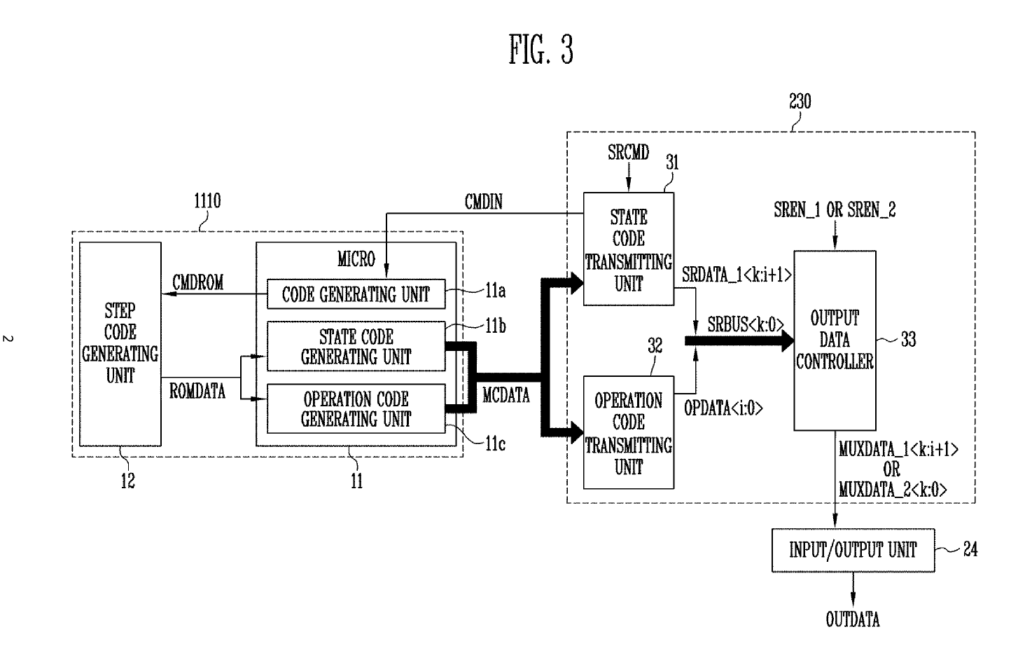

Referring to FIG. 2, a block diagram for describing the memory chip according to an embodiment of the invention is described.

In FIG. 2, the memory chip 200 may include a memory cell array 210 in which data is stored, a circuit group 220 configured so as to perform an erase operation, a program operation, and a read operation on the memory cell array 210, and a control logic 230 configured so as to control a circuit group 220. The invention will be described based on the flash memory device.

The memory cell array 210 includes a plurality of memory blocks (not illustrated). Further, the memory blocks include a plurality of cell strings (not illustrated). For example, the cell strings include a drain select transistors, memory cells, and source select transistors, and are electrically coupled to bit lines BL. Gates of the drain select transistors are electrically coupled to drain select lines DSL, gates of the memory cells are electrically coupled to word lines WL, and gates of the source select transistors are electrically coupled to source select lines SSL.

The circuit group 220 includes a voltage generating circuit 21, a row decoder 22, a column decoder 23, and an input/output unit 24.

The voltage generating circuit 21 generates operation voltages Vp necessary for various operations in response to an operation command OP_CMD. For example, the voltage generating circuit 21 generates an erase voltage, a program voltage, a read voltage, and the like as the operation voltages Vp.

The row decoder 22 transmits the operation voltages Vp to drain select lines DSL, word lines WL, and source select lines SSL electrically coupled to a memory block selected from among the plurality of memory blocks included in the memory cell array 210 in response to a road address RADD.

The column decoder 23 transceives data with the memory cell array 210 in response to the column address CADD.

The input/output unit 24 receives a command CMD and an address ADD from the outside, transmits a state checking command SRCMD and the address ADD to the control logic 230, and transceives data with the control logic 230 or the column decoder 23. Further, the input/output unit 24 receives data DATA including an operation code and various information from the control logic 230. The input/output unit 24 also outputs the received data DATA and various information as final data OUTPUT while performing a state checking operation.

The control logic 230 outputs an operation command OP_CMD, a row address RADD, a column address CADD, and data DATA in response to the state checking command SRCMD or commands related to various operations and the address ADD.

Referring to FIG. 3, a block diagram for describing the control logic and the storage device controller in detail is described.

In FIG. 3, when the control logic 230 receives the state checking command SRCMD, the control logic 230 outputs a state checking operation command CMDIN to the storage device controller 1110. The storage device controller 1110 outputs microdata MCDATA including an operation code related to an operation currently performed in the memory chip 200 in response to the state checking operation command CMDIN. When the control logic 230 receives the microdata MCDATA, the control logic 230 outputs first mux data MUXDATA_1<k:i+1> or second mux data MUXDATA_2<k:0> in response to first or second state checking enable signal SREN_1 or SREN_2. The input/output unit 24 outputs the first or second mux data MUXDATA_1<k:i+1> or MUXDATA_2<k:0> output from the control logic 230 as the final data OUTPUT.

Configurations of the control logic 230 and the storage device controller 1110 for the state checking operation will be described in more detail below.

The control logic 230 may include a state code transmitting unit 31, an operation code transmitting unit 32, and an output data controller 33, and the storage device controller 1110 may include a micro 11 and a step code generating unit 12.

When the state code transmitting unit 31 receives a state checking command SRCMD, the state code transmitting unit 31 outputs a state checking operation command CMDIN to the storage device controller 1110 so that the storage device controller 1110 may perform the state checking operation. The state checking operation command CMDIN is synchronized to the state checking command SRCMD to be output. The state checking command SRCMD may be transmitted to the state code transmitting unit 31 through the input/output unit 24. When the state checking operation command CMDIN is applied to the micro 11, the micro 11 outputs a data generating code CMDROM. Further, the step code generating unit 12 generates a step code in response to the data generating code CMDROM, and outputs ROM data ROMDATA including the step code. The step code generating unit 12 may continuously update the step code according to the operation of the storage device controller 1110. The micro 11 generates a state code and an operation code in response to the ROM data ROMDATA, and outputs micro data MCDATA including the state code and the operation code.

The micro 11 will be described in more detail. The micro 11 may include a code generating unit 11a, a state code generating unit 11b, and an operation code generating unit 11c. When the code generating unit 11a receives the state checking operation command CMDIN, the code generating unit 11a generates a data generating code CMDROM so that the step code generating unit 12 generates a step code. The code generating unit 11a may generate the data generating code CMDROM while being synchronized to the state checking operation command CMDIN. Each of the state code generating unit 11b and the operation code generating unit 11c simultaneously receives the ROM data ROMDATA, then generates a state code or an operation code, and further outputs micro data MCDATA including the state code and the operation code.

The step code means a code corresponding to a currently performed operation among various steps included in the operation performed by the memory chip 200. Based on the program operation as an example, the program operation may be segmentalized into a program set-up step, a program step, a verification step, and a discharge step. A uniform code is assigned to each of the segmentalized steps and is called a “step code.” Further, when the number of segmentalized steps is large, it is possible to provide a user with more accurate information so that the number of segmentalized steps may be variously set according to a semiconductor system. Based on the erase operation as an example, the erase operation may be segmentalized into an erase set-up step, an erase step, a verification step, and a discharge step. According to the read operation as an example, the read operation may be segmentalized into a read set-up step, a read step, an error correction checking step, and a discharge step. The erase operation and the read operation may be further segmentalized than the aforementioned steps according to a semiconductor memory device.

According to the program operation as an example, the respective steps are sequentially performed while the program operation is performed, so that the step code generating unit 12 continuously generates a step code according to a performed step. Data for a step code is not generated and accumulated whenever a step is changed, but may be generated in a method of being continuously updated at a specific storage place. Even when the operation of the memory chip 200 is performed, data capacity for a step code is not increased. When the step code generating unit 12 receives the data generating code CMDROM, the step code generated at a reception time of the data generating code CMDROM and information about the currently performed operation are output while being included in the ROM data ROMDATA.

The state code generating unit 11b generates a state code in response to the ROM data ROMDATA. Further, the operation code generating unit 11c generates an operation code in response to the ROM data ROMDATA. Accordingly, micro data MCDATA including the state code generated by the state code generating unit 11b and the operation code generated by the operation code 11c is output. The data corresponding to the state code may include information of a superordinate concept than that of the data corresponding to the operation code. For example, when the program operation is being performed by the memory chip, and the verification step in the program operation is being performed, information about the program operation may be recognized from the state code. In addition, information about the verification step may be recognized from the operation code. Accordingly, the state codes and the operation codes may be set for the operations of superordinate concepts and steps of subordinate concepts included in each operation, respectively.

TABLE 1

| Operation | Step | Operation code |
|---|---|---|
| Program | Program set-up | 0000 |
| | Program | 0001 |
| | Verification | 0010 |
| | Discharge | 0011 |
| Erase | Erase set-up | 0100 |
| | Erase | 0101 |
| | Verification | 0110 |
| | Discharge | 0111 |
| Read | Read set-up | 1000 |
| | Read | 1001 |
| | Error correction check | 1010 |
| | Discharge | 1011 |
| Other | . . . | 1100~1111 |

Referring to “Table 1,” each of the program operation, the erase operation, the read operation, and other operations is segmentalized into a plurality of steps. Further, a different operation code may be set for each of the segmentalized steps.

Among them, based on the program operation as an example, an operation code corresponding to the program set-up step may be set to 0000, an operation code corresponding to the program step may be set to 0001, an operation code corresponding to the verification step may be set to 0010, and an operation code corresponding to the discharge step may be set to 0011. The micro 11 generates an operation code corresponding to each step according to a step code included in the ROM data ROMDATA. The operation code may be selected in a table pre-stored in the micro, or coded so as to be generated according to an input step code.

The operation code included in the micro data MCDATA is transmitted to the operation code transmitting unit 32. Further, the remaining step codes except for the operation code are transmitted to the state code transmitting unit 31.

The state code transmitting unit 31 outputs the state code included in the micro data MCDATA as state code data SRDATA_1<K:i+1>. In addition, the operation code transmitting unit 32 outputs the operation code included in the micro data MCDATA as operation code data OPDATA<i:0>. The state code may be the same data as the state code data SRDATA_1<K:i+1>. Further, the operation code may be the same data as the operation code data OPDATA<i:0>. The state code data SRDATA_1<K:i+1> and the operation code data OPDATA<i:0> are loaded to the common bus SRBUS<k:0>. In particular, the operation code data OPDATA<i:0> may be allocated to the remaining areas, except for an area to which the state code data SRDATA_1<K:i+1> is allocated, within the common bus SRBUS<k:0>.

The output data controller 33 receives the state code data SRDATA_1<K:i+1> and the operation code data OPDATA<i:0> through the common bus SRBUS<k:0>. The output data controller 33 also outputs first mux data MUXDATA_1<k:i+1> or second mux data MUXDATA_2<k:0> in response to a first state checking enable signal SREN_1 or a second state checking enable signal SREN_2. For example, when the first state checking enable signal SREN_1 is output to the output data controller 33, the output data controller 33 outputs the first mux data MUXDATA_1<k:i+1> including the state code data SRDATA_1<K:i+1>, except for the operation code data OPDATA<i:0>. Further, when the second state checking enable signal SREN_2 is output to the output data controller 33, the output data controller 33 outputs the second mux data MUXDATA_2<k:0> including the operation code data OPDATA<i:0> and the state code data SRDATA_1<K:i+1>. The output data controller 33 selectively outputs the operation code data OPDATA<i:0> in response to the first or second state checking enable signal SREN_1 or SREN_2.

The input/output unit 24 receives the first or second mux data MUXDATA_1<k:i+1> or MUXDATA_2<k:0>, and outputs final data OUTPUT including the received first or second mux data MUXDATA_<k:i+1> or MUXDATA_2<k:0>. When the second mux data MUXDATA_2<k:0> is included in the final data OUTDATA, a user may recognize a specific step of a specific operation currently performed in the memory chip 200 based on the operation code data OPDATA<i:0> included in the second mux data MUXDATA_2<k:0> in real time.

The aforementioned step codes and operation codes will be described in more detail.

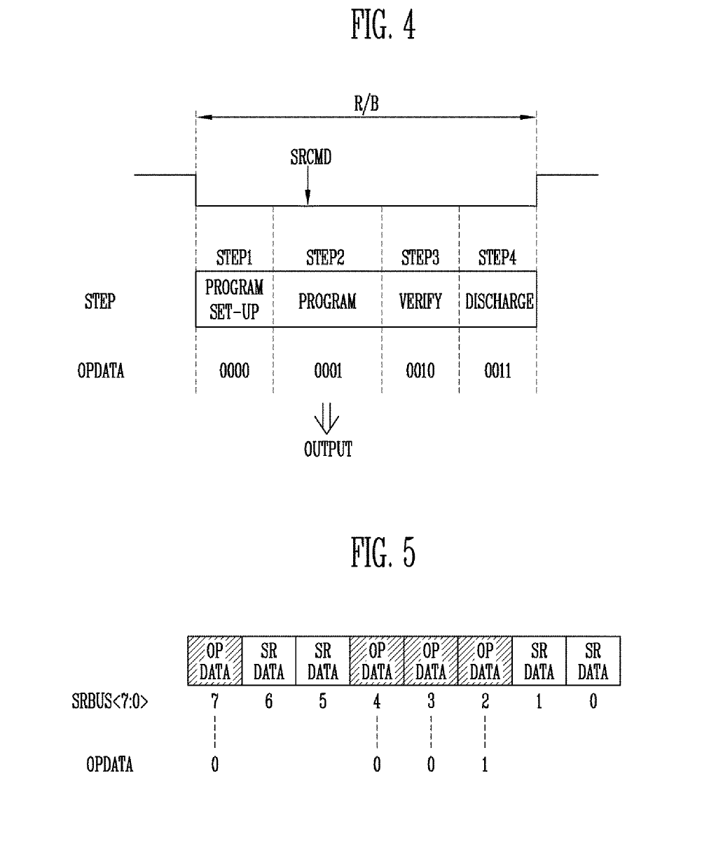

Referring to FIG. 4, a diagram for describing the step code and the operation code in detail is described.

In FIGS. 3 and 4, when the memory chip 200 is being operated, a ready busy (R/B) signal indicating that the memory chip 200 is in a state of currently being operated is maintained in a low state. Accordingly, when the state code transmitting unit 31 receives the state checking command SRCMD in a state where the R/B signal is in a low state, the step code generating unit 12 generates a step code STEP corresponding to a reception time of the state checking command SRCMD.

According to the program operation as an example, the program operation may be segmentalized into a program set-up step STEP1, a program step STEP2, a verification step STEP3, and a discharge step STEP4. The program set-up step STEP1 may be a step for setting various configurations necessary for the program operation. For example, configurations of a program voltage, a pass voltage, a voltage application time, and the like may be set up. The program step STEP2 may be a step for increasing threshold voltages of selected memory cells by applying a program voltage to a selected word line. The verification step STEP3 may be a step for determining whether the threshold voltages of the selected memory cells increase to a target level. The discharge step STEP4 may be a step for discharging various lines for a subsequent operation.

When the state checking command SRCMD is received while the program step STEP2 is being performed, the step code generating unit 12 generates a step code corresponding to the program step STEP2. In addition, the micro 11 generates the operation code OPDATA in response to the step code. The operation code OPDATA is set to a different code according to each step code. For example, the operation code OPDATA corresponding to the program set-up step STEP1 may be set to 0000, the operation code OPDATA corresponding to the program step STEP2 may be set to 0001, the operation code OPDATA corresponding to the verification step STEP3 may be set to 0010. Further, the operation code OPDATA corresponding to the discharge step STEP4 may be set to 0011. As described above, when the operation code is set by a code of 4 bits, the respective steps performed in the program operation, the erase operation, and the read operation may be discriminated by operation codes from 0000 to 1111. Accordingly, when the state checking command SRCMD is received while the program step STEP2 is being performed, the operation code generating unit 11c generates an operation code of 0001. The operation code of 0001 is output to the second mux data MUXDATA_2<k:0> output from the input/output unit 24 together with the state code. Further, the user may recognize an operation currently performed by the memory chip 200 and a detailed step of the operation based on the state code and the operation code included in the second mux data MUXDATA_2<k:0>.

The aforementioned operation code OPDATA is output as the operation code data OPDATA<i:0> through the operation code transmitting unit 32 and loaded to the common bus SRBUS<k:0>. Further, the operation code data OPDATA<i:0> may be loaded to the common bus SRBUS<k:0> without expansion of the common bus SRBUS<k:0>. This will be described in detail with reference to FIG. 5.

Referring to FIG. 5, a diagram for describing a method of loading the operation code data to the common bus in detail is described.

In FIG. 5, data of k+1 bits may be loaded to the common bus SRBUS<k:0>. For example, when data of 8 bits is loaded to the common bus SRBUS<k:0>, a value of k is 7. An area, to which the state code data SRDATA_1<K:i+1> is to be loaded, is allocated to eight storage areas of the common bus SRBUS<7:0>, but all of the eight storage areas are not used, so that an extra area exists within the common bus SRBUS<7:0>. For example, when the state code data SRDATA_1<K:i+1> is formed of a code of 4 bits, the state code SRDATA may be loaded to areas 0, 1, 5, and 6 of the bus SRBUS<7:0>. Further, the remaining areas 2, 3, 4, and 7 may be extra areas. Accordingly, the operation code OPDATA of 4 bits may be loaded to the extra areas of the bus SRBUS<7:0> by every 1 bit.

As described above, it is possible to check an operation state even when the memory chip 200 is being operated in real time, and provide detailed information about each operation, thereby improving reliability of the semiconductor system.

As described above, an embodiment has been disclosed in the figures and the specification. The specific terms used are for purposes of illustration, and do not limit the scope of the invention defined in the claims. Accordingly, those skilled in the art will appreciate that various modifications and another equivalent example may be made without departing from the scope and spirit of the invention. Therefore, the sole technical protection scope of the invention will be defined by the technical spirit of the accompanying claims.

What is claimed is:

1. A semiconductor memory device, comprising:
a micro configured to output a data generating code according to a state checking operation command; and
a step code generating unit configured to generate a step code for an operation currently performed by a storage device according to the data generating code, and output ROM data including the step code,
wherein the micro generates a state code for the operation currently performed by the storage device and an operation code for a segmentalized step of the operation according to the ROM data.

2. The semiconductor memory device of claim 1, wherein the step code generating unit continuously updates the step code according to the operation of the storage device.

3. The semiconductor memory device of claim 1, wherein the step code generating unit includes the step code, which has been generated when the data generating code is input, into the ROM data.

4. The semiconductor memory device of claim 1, wherein the micro includes:
a code generating unit configured to generate the data generating code in response to the state checking operation command;
a state code generating unit configured to generate the state code in response to the ROM data; and
an operation code generating unit configured to generate the operation code in response to the ROM data.

5. The semiconductor memory device of claim 4, wherein the code generating unit generates the data generating code while being synchronized to the state checking operation command.

6. The semiconductor memory device of claim 4, wherein the state code generating unit generates data for the operation currently performed by the storage device among the ROM data as the state code.

7. The semiconductor memory device of claim 4, wherein the operation code generating unit generates data for the segmentalized step of the operation currently performed by the storage device among the ROM data as the operation code.

8. The semiconductor memory device of claim 1, wherein the storage device includes a plurality of memory chips.

9. The semiconductor memory device of claim 8, wherein the memory chips are configured by a Dynamic Random Access Memory (DRAM), a Static Random Access Memory (SRAM), a Magnetic Random Access Memory (MRAM), or a flash memory device including a control logic configured to output data for an operation state of the storage device in response to micro data output by the storage device.

10. The semiconductor memory device of claim 9, wherein the control logic includes:
a state code transmitting unit configured to output the state checking operation command in response to a state checking command, generate the state code as state code data, and load the generated state code data to a common bus;
an operation code transmitting unit configured to generate the operation code as operation code data, and load the generated operation code data to the common bus; and
an output data controller configured to receive the state code data and the operation code data through the common bus, and output the state code data or output the state code data and the operation code data according to a first state checking enable signal or a second state checking enable signal.

11. The semiconductor memory device of claim 10, wherein the state code data and the operation code data are loaded to allocated areas of the common bus, respectively.

12. The semiconductor memory device of claim 10, wherein when the first state checking enable signal is received, the output data controller outputs the state code data except for the operation code data, and when the second state checking enable signal is received, the output data controller outputs the state code data and the operation code data.

13. A method of checking an operation state of a semiconductor memory device, comprising:
setting a step code for each operation performed by a storage device;
generating the step code for one operation currently performed by the storage device according to a state checking command;
generating a state code for the one operation currently performed by the storage device and an operation code for a segmentalized step of the one operation according to the step code; and
outputting data including the operation code according to a state checking enable signal.

14. The method of claim 13, wherein the state code is set to a code by which each of a program operation, an erase operation, and a read operation performed by the storage device is discriminated.

15. The method of claim 13, wherein each of a program operation, an erase operation, and a read operation performed by the storage device is segmentalized into a plurality of steps, and the operation code is set to a code by which each of the segmentalized steps is discriminated.

16. The method of claim 14, wherein the program operation is segmentalized into a program set-up step, a program step, a verification step, and a discharge step.

17. The method of claim 14, wherein the erase operation is segmentalized into an erase set-up step, an erase step, a verification step, and a discharge step.

18. The method of claim 14, wherein the read operation is segmentalized into a read set-up step, a read step, an error correction checking step, and a discharge step.
